(19) United States
(12) Patent Application Publication
(10) Pub. No.: US 2026/0190947 A1
(43) Pub. Date: Jul. 2, 2026

(54) REACTOR SYSTEM WITH POROUS LIFT PIN

(71) Applicant: ASM IP Holding B.V., Almere (NL)

(72) Inventors: Hang Zhang, Tempe, AZ (US); Shaofeng Chen, Austin, TX (US); Shubham Garg, Gilbert, AZ (US); Todd Robert Dunn, Cave Creek, AZ (US)

(21) Appl. No.: 19/432,307

(22) Filed: Dec. 24, 2025

Related U.S. Application Data
(60) Provisional application No. 63/740,000, filed on Dec. 30, 2024.

(51) Int. Cl. H10P 72/76; C23C 16/44; C23C 16/458

(52) U.S. Cl. CPC H10P 72/7612; C23C 16/4408; C23C 16/458; H10P 72/7624

(57) ABSTRACT

A reactor system can comprise a reaction chamber; and/or a susceptor disposed in the reaction chamber between an upper chamber and a lower chamber of the reaction chamber. The susceptor can comprise a substrate support surface; and/or a fluid path disposed through the susceptor and the substrate support surface fluidly connecting the upper chamber and the lower chamber. The lower chamber can comprise a lower chamber pressure that is greater than an upper chamber pressure of the upper chamber, such that fluid flows from the lower chamber through the fluid path into the upper chamber. The susceptor can further comprise a pin hole disposed through the susceptor, and a lift pin can be disposed in the pin hole. The lift pin can comprise a porous material and/or a pin channel that comprises the fluid path such that the fluid flows through the lift pin.

### CROSS-REFERENCE TO RELATED APPLICATIONS

This application is a nonprovisional of, and claims priority to and the benefit of, U.S. Provisional Patent Application No. 63/740,000 , filed Dec. 30, 2024 and entitled “REACTOR SYSTEM WITH POROUS LIFT PIN,” which is hereby incorporated by reference herein.

### FIELD OF THE DISCLOSURE

The present disclosure relates generally to a semiconductor processing or reactor system, and particularly a semiconductor reactor system, and components comprised therein, which prevents material deposition on undesirable locations of, for example, the reactor system and/or a substrate.

### BACKGROUND OF THE DISCLOSURE

Reaction chambers can be used for depositing various material layers onto substrates. A substrate can be placed on a susceptor inside a reaction chamber. Both the substrate and the susceptor can be heated to a desired substrate temperature set point. In an example substrate treatment process, one or more reactant gases can be passed over a heated substrate, causing the deposition of a thin film of material on the substrate surface. Throughout subsequent deposition, doping, lithography, etch, and other processes, these layers can be made into integrated circuits.

During operation of the reactor system, undesirable contaminants can accumulate on and/or coat an underside of the substrate (i.e., the surface of the substrate proximate the susceptor) and/or edge of the substrate. Apparatus and methods are therefore desirable for preventing deposition or contamination on an underside and/or edge of a substrate.

### SUMMARY OF THE DISCLOSURE

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

In various examples, a reactor system is provided. In various examples, a reactor system can comprise a reaction chamber; a susceptor disposed in the reaction chamber, wherein the susceptor is disposed between an upper chamber and a lower chamber comprised in the reaction chamber; wherein the susceptor can comprise a pin hole disposed through the susceptor such that the pin hole is in fluid communication with the upper chamber and the lower chamber, and such that the upper chamber is in fluid communication with the lower chamber; and/or a lift pin disposed in the pin hole. The lift pin can comprise a pin body. The pin body can comprise a porous material configured to allow a fluid to flow through the lift pin between the upper chamber and the lower chamber. The upper chamber can be substantially fluidly sealed from the lower chamber except through the pin hole with the lift pin disposed therein. The lower chamber can comprise a lower chamber inlet through which fluid flows into the lower chamber. The lower chamber can comprise a lower chamber pressure and the upper chamber can comprise an upper chamber pressure, wherein the lower chamber pressure can be greater than the upper chamber pressure, such that fluid flows from the lower chamber through the porous material in the lift pin into the upper chamber. The porous material can comprise a sintered material.

The pin body can further comprise a solid portion surrounding the porous material. The solid portion of the pin body can be a solid sleeve. The porous material can be disposed in the solid sleeve. The lift pin can comprise a pin head at a top end of the pin body, wherein the pin head can comprise the porous material. The pin head can be disposed at least partially in the pin hole of the susceptor.

In various examples, the susceptor can comprise a support surface configured to support a substrate. The support surface can comprise a susceptor channel recessed into the susceptor that is open to the support surface and in fluid communication with the pin hole. The susceptor channel in the susceptor can be configured to allow fluid to flow from the pin hole and through the susceptor channel when the substrate is disposed on the support surface, such that the fluid flows under the substrate and is configured to purge contaminants from under the substrate.

In various examples, a lift pin configured to be disposed in a susceptor comprised in a reactor system can comprise a pin body comprising a porous material. The porous material can be configured to allow a fluid to flow through at least a portion of the pin length. The porous material can comprise a sintered material. The pin body can further comprise a solid portion surrounding the porous material. The solid portion of the pin body can be a solid sleeve, wherein the porous material can be disposed in the solid sleeve.

In various examples, a reactor system can comprise a reaction chamber; and/or a susceptor disposed in the reaction chamber. The susceptor can be disposed between an upper chamber and a lower chamber comprised in the reaction chamber. The susceptor can comprise a support surface configured to support a substrate; and/or a fluid path disposed through the susceptor and the support surface. The fluid path can fluidly connect the upper chamber and the lower chamber. The lower chamber can comprise a lower chamber pressure, and the upper chamber can comprise an upper chamber pressure. The lower chamber pressure can be greater than the upper chamber pressure, such that fluid flows from the lower chamber through the fluid path into the upper chamber. The susceptor can further comprise a susceptor channel recessed into the susceptor through the support surface that is open to the support surface and fluidly connected to the fluid path. The susceptor can further comprise a pin hole disposed through the susceptor. The reactor system can further comprise a lift pin disposed in the pin hole. The lift pin can comprise the fluid path such that the fluid flows through the lift pin. The lift pin can comprise a porous material. The porous material can comprise the fluid path. The porous material can comprise a sintered material. The pin body can further comprise a solid portion surrounding the porous material.

For the purpose of summarizing the disclosure and the advantages achieved over the prior art, certain objects and advantages of the disclosure have been described herein above. Of course, it is to be understood that not necessarily all such objects or advantages can be achieved in accordance with any particular example of the disclosure. Thus, for example, those skilled in the art will recognize that the examples disclosed herein can be carried out in a manner that achieves or optimizes one advantage or group of advantages as taught or suggested herein without necessarily achieving other objects or advantages as may be taught or suggested herein.

All of these examples are intended to be within the scope of the disclosure. These and other examples will become readily apparent to those skilled in the art from the following detailed description of certain examples having reference to the attached figures, the disclosure not being limited to any particular example(s) discussed.

### BRIEF DESCRIPTION OF THE DRAWING FIGURES

While the specification concludes with claims particularly pointing out and distinctly claiming what are regarded as examples of the disclosure, the advantages of examples of the disclosure may be more readily ascertained from the description of certain examples of the disclosure when read in conjunction with the accompanying drawings. Elements with the like element numbering throughout the figures are intended to be the same.

FIG. 1 is a schematic diagram of an exemplary reactor system, in accordance with various examples.

FIG. 2A is a schematic diagram of an exemplary reaction chamber with a susceptor disposed in a lower position, in accordance with various examples.

FIG. 2B is a schematic diagram of an exemplary reaction chamber with a susceptor disposed in a raised position, in accordance with various examples.

FIG. 3 is a schematic diagram of another exemplary reaction chamber, in accordance with various examples.

FIG. 4 illustrates a side view of a lift pin, in accordance with various examples.

FIG. 5A illustrates a cross-sectional view of a portion of a lift pin for a reactor system, in accordance with various examples.

FIG. 5B illustrates a portion of a lift pin for a reactor system, in accordance with various examples.

FIG. 5C illustrates a cross-sectional view of a top portion of a lift pin for a reactor system, in accordance with various examples.

FIG. 6A illustrates a cross-sectional top view of a lift pin for a reactor system comprising a porous material, in accordance with various examples.

FIG. 6B illustrates a cross-sectional perspective top view of a lift pin for a reactor system comprising a porous material, in accordance with various examples.

FIG. 7 illustrates a cross-sectional perspective top view of another lift pin for a reactor system comprising a porous material, in accordance with various examples.

FIG. 8 illustrates a cross-sectional perspective top view of another lift pin for a reactor system comprising a porous material, in accordance with various examples.

FIG. 9 illustrates exemplary porous materials with various media types and/or grades, in accordance with various examples.

FIG. 10 illustrates a method for processing a substrate in a reactor system, in accordance with various examples.

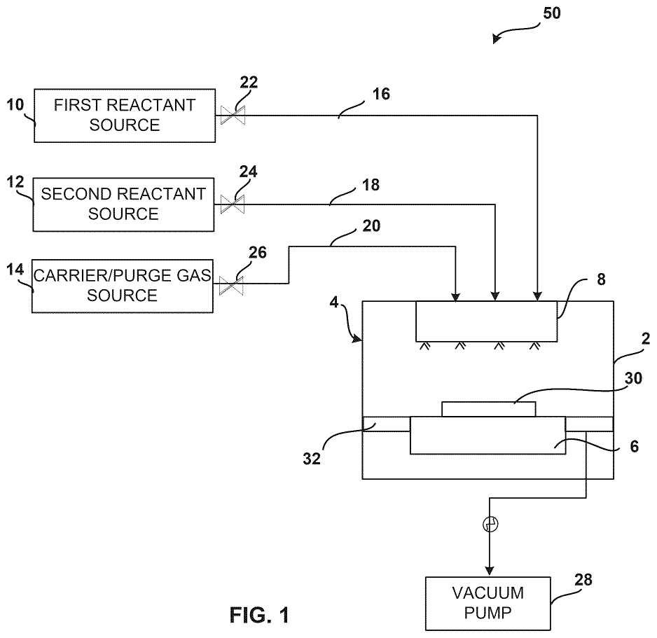

### DETAILED DESCRIPTION

The description of examples of methods, structures, devices, and systems provided below is merely exemplary and is intended for purposes of illustration only—the following description is not intended to limit the scope of the disclosure or the claims. Moreover, recitation of multiple examples having stated features is not intended to exclude other examples having additional features or other examples incorporating different combinations of the stated features. For example, various examples are set forth as embodiments and may be recited in the dependent claims. Unless otherwise noted, the examples or components thereof can be combined or can be applied separately from each other. Methods can include the disclosed steps in any suitable and/or desired order or combination.

As used herein, the term “and/or” includes any and all combinations of one or more of the associated listed items. Unless otherwise noted, expressions such as “at least one of,” when preceding a list of elements, modify the entire list of elements and do not necessarily modify the individual elements of the list.

As used herein, the terms “includes,” “comprises,” “including,” and/or “comprising” specify the presence of stated features, integers, steps, processes, members, components, and/or groups thereof, but do not preclude the presence or addition of one or more other features, integers, steps, processes, members, components, and/or groups thereof. In this disclosure, any defined meanings do not necessarily exclude ordinary and customary meanings in some examples.

As used herein, the term “substrate” can refer to any underlying material or materials that can be used, or upon which, a device, a circuit, or a film can be formed.

As used herein, the term “atomic layer deposition” (ALD) can refer to a vapor deposition process in which deposition cycles are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) can subsequently be introduced into the process chamber for use in converting the chemisorbed precursor to the desired material on the deposition surface. Typically, this reactant is capable of further reaction with the precursor. Further, purging steps can also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) can refer to any process wherein a substrate is exposed to one or more volatile precursors, which react and/or decompose on a substrate surface to produce a desired deposition.

As used herein, the term “film” and “thin film” can refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” can comprise material or a layer with pinholes, but still be at least partially continuous.

As used herein, the term “contaminant” can refer to any unwanted material disposed within the reaction chamber that can affect the purity of a substrate disposed in the reaction chamber. The term “contaminant” can refer to, but is not limited to, unwanted deposits, metal and non-metal particles, impurities, and waste products, disposed within the reaction chamber.

Reactor systems used for ALD, CVD, and/or the like, can be used for a variety of applications, including depositing and etching materials on a substrate surface. In various examples, a reactor system 50 can comprise a reaction chamber 4, a susceptor 6 to hold a substrate 30 during processing, a fluid distribution system 8 (e.g., a showerhead) to distribute one or more reactants to a surface of substrate 30, one or more reactant sources 10, 12, and/or a carrier and/or purge gas source 14, fluidly coupled to reaction chamber 4 via lines 16-20 and valves or controllers 22-26. System 50 can also comprise a vacuum source 28 fluidly coupled to the reaction chamber 4.

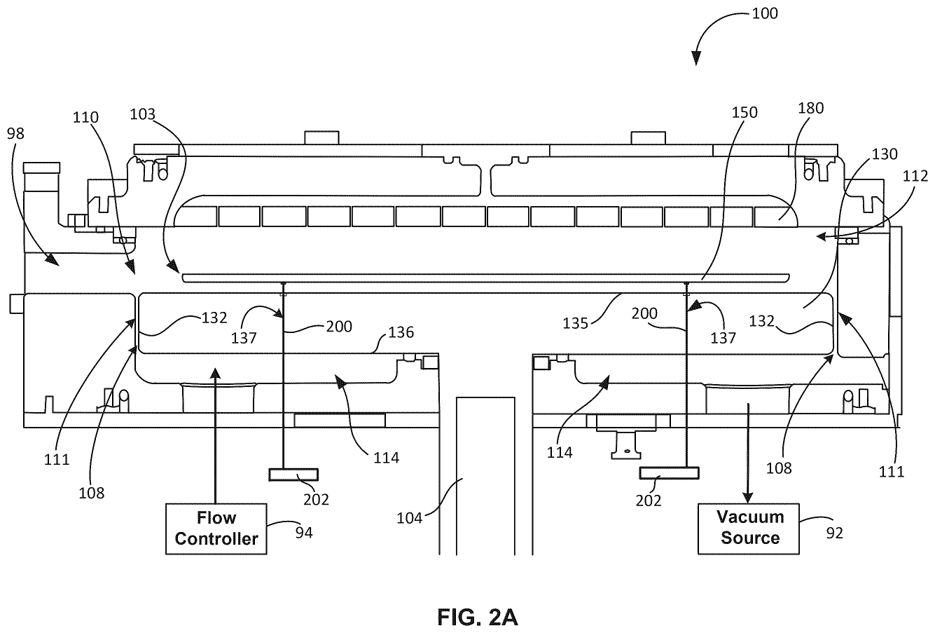

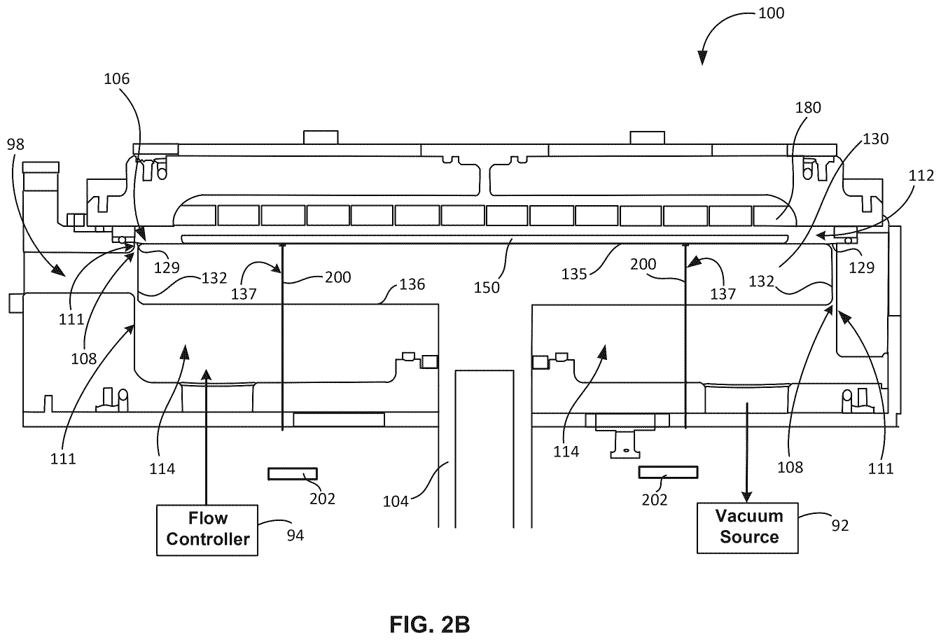

Turning to FIGS. 2A and 2B, the examples of the disclosure can include reactor systems and methods that can be utilized for processing a substrate within a reactor 100. In various examples, a reactor 100 can comprise a reaction chamber 110 for processing substrates. In various examples, reaction chamber 110 can comprise an upper chamber 112 (i.e., a reaction space), which can be configured for processing one or more substrates, and/or a lower chamber 114 (i.e., a lower chamber). Lower chamber 114 can be configured for the loading and unloading of substrates from the reaction chamber, and/or for providing a pressure differential between lower chamber 114 and upper chamber 112.

In various examples, upper chamber 112 and lower chamber 114 can be separated by a susceptor 130 disposed in reaction chamber 110. In various examples, upper chamber 112 and lower chamber 114 can be substantially fluidly separate or isolated from one another. For example, a susceptor 130 can substantially fluidly separate upper chamber 112 and lower chamber 114 by creating at least a partial seal (i.e., at least restricting fluid flow) between susceptor 130 and a chamber sidewall 111 of reaction chamber 110 disposed proximate a susceptor outer side surface 132 of susceptor 130. That is, space 108 between susceptor 130 and chamber sidewall 111 can be minimized or eliminated such that there is little or no fluid movement between susceptor 130 and chamber sidewall 111 (i.e., a substantial seal therebetween).

In various examples, to prevent or reduce fluid flow between susceptor 130 and chamber sidewall 111, one or more sealing members (e.g., sealing members 129) can extend from susceptor 130 (e.g., from susceptor outer side surface 132) and/or from chamber sidewall 111 of reaction chamber 110 to the other, creating at least a partial seal (i.e., restricting or preventing fluid flow) between susceptor 130 and chamber sidewall 111. Thus, upper chamber 112 from lower chamber 114 can be substantially sealed from one another. The at least partial sealing of upper chamber 112 from lower chamber 114 can be desirable to prevent or reduce precursor gases, and/or other fluids, utilized in the processing of a substrate 150, from entering and/or contacting lower chamber 114 of reaction chamber 110. For example, the precursor gases utilized for processing substrates in the upper chamber can comprise, corrosive deposition precursors which can contact lower chamber 114 producing unwanted deposits/contaminants/particles which can in turn be reintroduced into upper chamber 112 thereby providing a source of contamination to a substrate disposed in the upper chamber.

In various examples, although sealing members 129 extending between susceptor 130 and chamber sidewall 111 of reaction chamber 110, and/or the at least partial seal formed by direct contact between susceptor 130 and chamber sidewall 111 of reaction chamber 110, can restrict or substantially prevent fluid communication between upper chamber 112 and lower chamber 114 through space 108, it may still be possible for a small volume of precursor gases to enter lower chamber 114 by diffusion, which can result in possible corrosion, unwanted deposition and contaminants, in the lower chamber of the reaction chamber of the reactor system.

In various examples, susceptor 130 can comprise one or more pin holes 137. Each pin hole 137 can span through susceptor 130 from a top surface of susceptor 130 (e.g., a substrate support surface 135 on which substrate 150 can be disposed for processing) to a bottom surface 136 of susceptor 130. The susceptor top surface (e.g., substrate support surface 135) can be the surface of susceptor 130 proximate upper chamber 112 of reaction chamber 110. Susceptor bottom surface 136 can be the surface of susceptor 130 proximate lower chamber 114 of reaction chamber 110. With no lift pin disposed in a pin hole 137, upper chamber 112 and lower chamber 114 can be in fluid communication with one another through pin hole 137. That is, pinhole(s) 137 can be in fluid communication with upper chamber 112 and lower chamber 114.

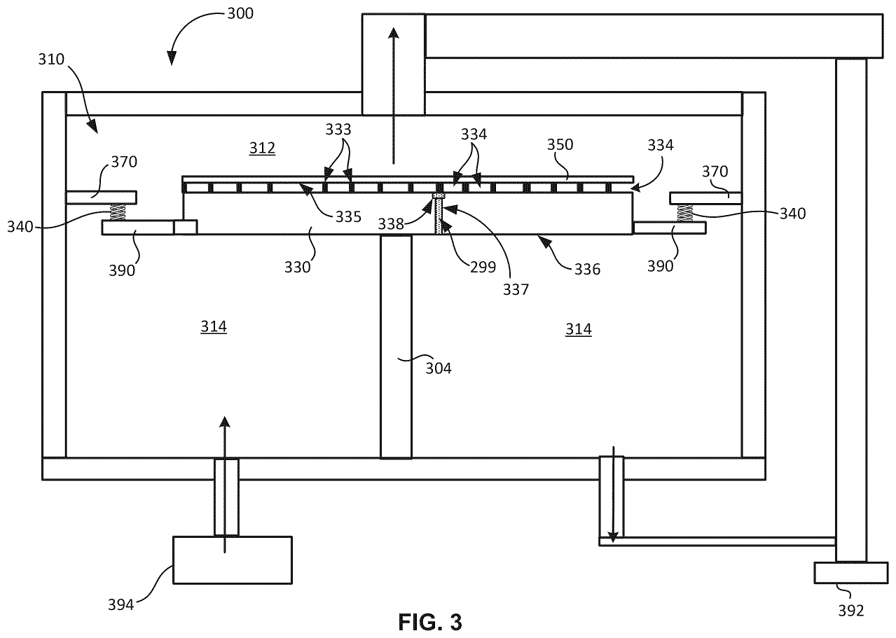

In various examples, with additional reference to FIG. 3, a reactor 300 can comprise similar components to reactor 100, including a reaction chamber 310 for processing substrates. In various examples, reaction chamber 310 (similar to reaction chamber 110) can comprise an upper chamber 312 (similar to upper chamber 112), which can be configured for processing one or more substrates, and/or a lower chamber 314 (similar to lower chamber 114). Lower chamber 314 can be configured for the loading and unloading of substrates from the reaction chamber, and/or for providing a pressure differential between lower chamber 314 and upper chamber 312.

In various examples, upper chamber 312 and lower chamber 314 can be separated by a susceptor 330 (similar to susceptor 130) disposed in reaction chamber 310. In various examples, upper chamber 312 and lower chamber 314 can be substantially fluidly separate or isolated from one another. For example, a susceptor 330, a flow control ring 370, and/or a spacer plate 390 can fluidly separate upper chamber 312 and lower chamber 314 by creating at least a partial seal (i.e., at least restricting fluid flow) therebetween (e.g., upper chamber 312 can be substantially sealed from lower chamber 314). Flow control ring 370 can be coupled to a wall of reaction chamber 310, and spacer plate can be coupled to susceptor 330, such that in response to susceptor being raised (e.g., via susceptor elevator 304), flow control ring 370 can create at least a seal with spacer plate 390. Flow control ring 370 can abut directly with spacer plate 390 to create the seal, and/or a sealing device 340 (e.g., an O-ring, a spring, and/or the like) can be disposed between flow control ring 370 and spacer plate 390 to create a seal. Thus, upper chamber 312 and lower chamber 314 can be fluidly separate.

Susceptor 330 can comprise substrate support surface 335 upon which a substrate 350 can be supported. Substrate support surface 335 can comprise one or more susceptor channels 334 recessed therein (susceptor channel 334 can be one continuous, or multiple separate, channels). Susceptor channel 334 can be disposed in, and/or recessed into, susceptor 330 and open to substrate support surface 335 (e.g., such that susceptor channel 334 is closed in response to a substrate 350 being disposed on substrate support surface 335). Susceptor channels 334 can result in ridges 333 between susceptor channels 334 to contact and support substrate 350 disposed on substrate support surface 335. Thus, only a portion of substrate support surface 335 below substrate 350 can contact substrate 350 (e.g., from 1% to 20% or 30% of the area of substrate support surface 335 under substrate 350 can contact substrate 350). Susceptor channel 334 can allow the backside of substrate 350 (the side facing susceptor 330) to be exposed to susceptor channel 334.

In various examples, susceptor 330 can comprise one or more pin holes 337 (similar to pin holes 137). Each pin hole 337 can span through susceptor 330 from a top surface of susceptor 330 (e.g., a substrate support surface 335 on which substrate 350 can be disposed for processing) to a bottom surface 336 of susceptor 330. The susceptor top surface (e.g., substrate support surface 135) can be the surface of susceptor 330 proximate upper chamber 312 of reaction chamber 310. Susceptor bottom surface 336 can be the surface of susceptor 330 proximate lower chamber 314 of reaction chamber 310. With no lift pin disposed in a pin hole 337, upper chamber 312 and lower chamber 314 can be in fluid communication with one another through pin hole 337. That is, pinhole(s) 337 can be in fluid communication with upper chamber 312 and lower chamber 314. Susceptor channel 334 in susceptor 330 can be in fluid communication with pin hole 337.

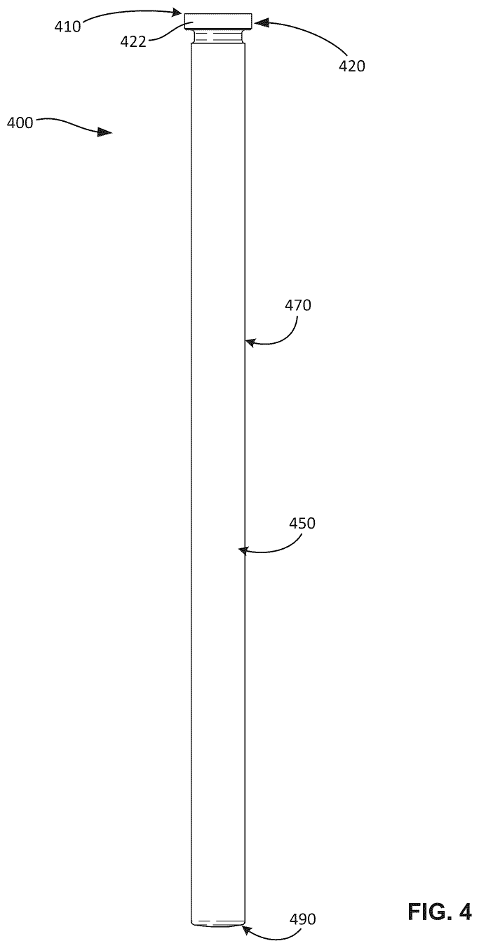

Reactor 300 can comprise a lift pin 299 (or other like object) that can be disposed in each pin hole 337 (e.g., lift pin 200 in pin hole 137 in FIGS. 2A and 2B). With additional reference to FIG. 4, a lift pin 400 (an example of lift pin 200 depicted in FIGS. 2A and 2B, and lift pin 299 in FIG. 3) can comprise a lift pin body 450, which is configured to span at least a portion of a pin hole 337 when disposed in pin hole 337. Pin body 450 can comprise a cross-sectional shape (in a cross section taken perpendicular to a length of pin body 450) that is complementary to a cross-sectional shape of pin hole 337. Pin body 450 can be defined by a pin outer surface 470. At least a portion of pin outer surface 470 is disposed adjacent to a pin hole surface defining pin hole 337 when lift pin 400 is disposed in pin hole 337. In various examples, pin outer surface 470 can form at least a partial seal with pin hole surface such that little or no fluid (e.g., a liquid or gas) can pass between pin outer surface 470 and the contacting pin hole surface 439. That is, there can be a substantial seal between lift pin 400 and the pin hole surface.

In various examples, lift pin 400 can comprise a pin top end 410 opposite a pin bottom end 490, wherein pin body 450 (and a pin length) spans therebetween. Pin top end 410 of lift pin 400 can comprise a pin head 420. Pin head 420 can be any suitable shape in comparison to pin body 450. In various examples, pin head 420 can comprise a cross-sectional shape (in a cross section taken perpendicular to length of pin body 450) that is the same as a cross-sectional shape of pin body 450. In various examples, pin head 420 can comprise a cross-sectional shape (in a cross section taken perpendicular to length of pin body 450) that comprises a greater or lesser surface area that a cross-sectional shape of pin body 450.

In examples in which pin head 420 comprises a greater surface area than a cross-sectional shape of pin body 450, the pin hole 337 in which lift pin 400 is disposed can comprise a pin head hole 338 having a cross-sectional shape complementary to that of pin head 420. Pin head 420 can be defined by a pin head outer surface 422. Pin head outer surface 422 can be disposed adjacent to the pin hole surface defining pin head hole 338 when lift pin 400 (e.g., lift pin 400) is disposed in pin hole 337. In various examples, pin head outer surface 422 can form at least a partial seal with (i.e., restrict fluid flow between pin head 420 and) the pin hole surface of pin head hole 338, such that little or no fluid (e.g., a liquid or gas) can pass between pin head 420 and pin head hole 338 of pin hole 337.

In various examples, pin top end 410 can be configured to contact substrate 350 to move substrate 350 relative to susceptor 330. For example, lift pin(s) 400 can cause substrate 350 to move up or down relative to susceptor 330 (i.e., increase or decrease the space between substrate 350 and susceptor 330).

With reference again to FIGS. 2A and 2B, substrate 150 and susceptor 130 can be movable relative to one another. For example, in various examples, one or more lift pins 400 (or lift pins 200 illustrated in FIGS. 2A and 2B) can be configured to allow substrate 150 to separate from susceptor 130, and to allow substrate 150 to be placed in contact with (i.e., to be supported by) susceptor 130. In various examples, susceptor 130 can move, for example via a susceptor elevator 104, up or down such that susceptor 130 moves relative to substrate 150. In various examples, lift pins 200 can move up or down, for example via lift pin elevators/platforms 202 such that substrate 150 moves relative to 130 susceptor. In various examples, susceptor 130 and/or lift pins 200 can be stationary while the other is moving. In various examples, susceptor 130 and/or lift pins 200 can be configured to move relative to the other.

In various examples, the reactor system can comprise a susceptor (e.g., susceptor 130) including three pin holes (e.g., pin holes 137) (or any suitable number of pin holes) with a corresponding lift pin (e.g., lift pin 400) disposed in each of the pin holes. Pin holes can be spaced in any suitable pattern on or throughout substrate support surface 135 (e.g., equidistantly in a perimeter on substrate support surface 135, in a pattern traversing substrate support surface 135, and/or the like). The lift pins can move in unison up and down relative to the susceptor (e.g., relative to the substrate support surface) to raise and lower the substrate (e.g., substrate 150). The substrate can be raised into a processing position (i.e., a raised position) (e.g., processing position 106 shown in FIG. 2B) within the reaction space (e.g., upper chamber 112) and/or lowered into a loading position (i.e., a lower position) (e.g., loading position 103 shown in FIG. 2A), for example. In various examples, the lift pins can be moved while the susceptor remains stationary, or the lift pins remain stationary while the susceptor is moved, to raise and lower the substrate relative to the susceptor. In various examples, the lift pins and the susceptor can move to raise and lower the substrate relative to the susceptor.

In various examples, lift pins 200 can facilitate removal of substrate 150 from reaction chamber 110 that might otherwise stick to susceptor 130, because of, for example, static friction between substrate 150 and susceptor 130. Lift pins 200 can facilitate separation of substrate 150 from susceptor 130 by the lift pins 200 and/or susceptor 130 moving relative to the other.

In various examples, for loading and/or unloading of substrate 150 from reaction chamber 110, substrate 150 can be disposed on lift pins 200. Disposing substrate 150 on lift pins 200, can facilitate loading or unloading of substrate 150 from reaction chamber 110, for example, through opening 98 in chamber sidewall 111.

In various examples, once substrate 150 is disposed on lift pins 200, substrate 150 can move from loading position 103 to processing position 106, receiving substrate 150 during such movement. In such embodiments, the pin top end and/or the pin heads (e.g., pin head 420) of lift pins 200 can be received by pin holes 137 (pin hole 337 in FIG. 3), and therefore, substrate 150 can directly contact susceptor 130. In various examples, the pin heads of lift pins 200 can be supported by a portion of pin hole 337 and/or pin head hole 338 complementary to the area of pin head 420 radially outward of pin body 450. Therefore, lift pins 200 can travel with susceptor 130 to processing position 106, lift pins 200 being disposed in pin holes 137 such that the pin top ends (e.g., pin top ends 410 of lift pins 400) are flush with and/or below substrate support surface 135.

In various examples, once substrate 150 is disposed on lift pins 200, lift pins 200 can move downward relative to, and into, susceptor 130 (e.g., by susceptor 130 moving upward), such that substrate 150 is received by susceptor 130 (i.e., such that substrate 150 rests on substrate support surface 135). In response, the pin top ends (e.g., pin top ends 410 of lift pins 400) can be flush with and/or below substrate support surface 135. Substrate 150 can be subsequently processed within the reaction chamber.

In various examples, one or more lift pins can comprise a fluid path through the respective lift pin, such that fluid can travel through a length of the respective lift pin. The fluid path in the lift pin can span a length of the lift pin such that when the lift pin is disposed in the respective pin hole in the susceptor, both the upper chamber and the lower chamber of the reaction chamber can be in fluid communication with the fluid path through the lift pin. Therefore, the fluid path in the lift pin can allow fluid communication between the upper chamber and the lower chamber when the lift pin is disposed in its respective pin hole. For example, the fluid path comprised in a lift can span a length of the lift pin that is equal to or larger than a thickness of the susceptor between the substrate support surface and the bottom surface of the susceptor (e.g., so gas can enter the fluid path in lower chamber 114, flow through the lift pin via the fluid path, and exit the fluid path into upper chamber 112).

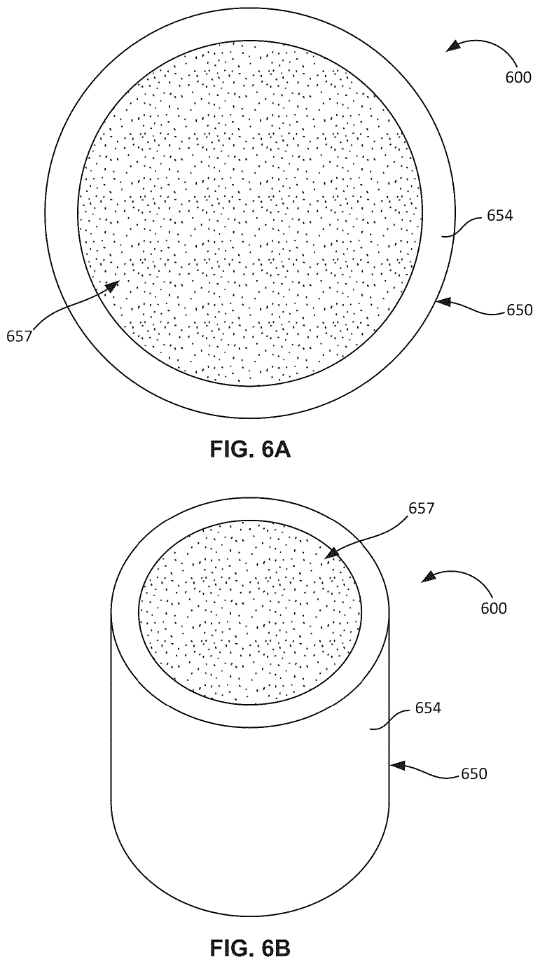

In various examples, a lift pin can comprise a porous material (e.g., in a pin body and/or pin head of the lift pin). The porous material can be configured to allow a fluid to flow through the lift pin disposed in the respective pin hole in the susceptor, and between the upper chamber and the lower chamber. That is, the porous material of the lift pin can comprise the fluid path fluidly coupling the upper chamber and the lower chamber. For example, lift pin 299 in FIG. 3 can comprise a porous material (e.g., made entirely of a porous material). In various examples, a portion (or portion of a length) of a lift pin can comprise a porous material having the fluid path. With reference to FIGS. 6A and 6B, lift pin 600 (a cross-section thereof is depicted) comprises a pin body 650. Lift pin 600 can have a full shape of lift pin 400 in FIG. 4, for example. Pin body 650 can comprise a solid portion 654 and a porous material 657. Solid portion 654 can be nonporous and may not allow fluid to pass therethrough. Porous material 657 can be in a solid state (e.g., not a powder, or the like) comprising pores allowing fluid to pass therethrough (e.g., comprising a fluid path). Solid portion 654 can be a solid material sleeve surrounding porous material 657. Porous material 657 can be disposed in the solid sleeve of solid portion 654 (e.g., solid portion 654 can at least partially, or fully, surround porous material 657, for example around a perimeter of a cross section of lift pin 600). Solid portion 654 can be open on both ends of the lift pin (e.g., on top and bottom ends), such that porous material 657 is exposed on the ends of solid portion 654. Thus, fluid can flow through porous material 657 (e.g., through the fluid path therethrough) between the upper chamber and the lower chamber of a reactor when lift pin 600 is disposed in a pin hole of the susceptor. Solid portion 654 can facilitate contact (e.g., smooth contact) with the pin hole within the susceptor, such that movement of the lift pin and/or susceptor relative to one another can be smooth and/or there is a substantial seal between solid portion 654 and the pin hole surface in the susceptor.

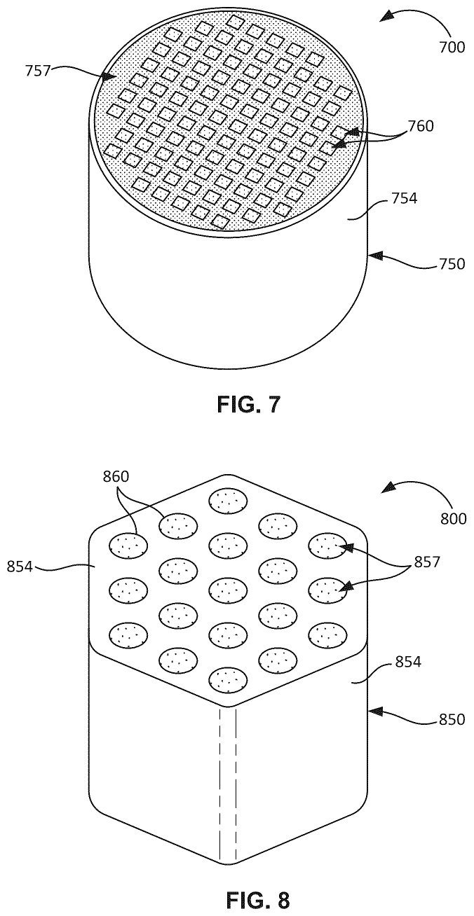

FIG. 7 depicts a cross-section of a lift pin 700. Lift pin 700 can have a full shape of lift pin 400 in FIG. 4, for example. Lift pin 700 can comprise a pin body 750. Pin body 750 can comprise a solid portion 754 (similar to solid portion 654 in FIG. 6) and a porous material 757 (similar to porous material 657 in FIG. 6). Porous material 757 can comprise porous channels 760 disposed through porous material 757 along at least a portion of a length of lift pin 700. Porous channels 760 can facilitate fluid flow through porous material 757.

The cross-sectional shape of a lift pin can be any suitable shape (e.g., a circle, oval, square, rectangle, diamond, triangle, hexagon, octagon, etc.). FIG. 8 depicts a cross-section of a lift pin 800. Lift pin 800 can have a full shape of lift pin 400 in FIG. 4, for example. Lift pin 800 can have a hexagonal cross-sectional shape. Lift pin 800 can comprise a solid portion 854 and a porous material 857. Solid portion 854 can comprise a plurality of holes 860 disposed therethrough along at least a portion of a length of lift pin 800. Porous material 857 can be disposed in holes 860. Porous material 857 in holes 860 can facilitate fluid flow through porous material 857.

The porous material comprised in a lift pin to facilitate fluid flow through the lift can comprise any suitable material, such as a metal (e.g., elemental metal), metal alloy, metal oxide, ceramic material, and/or the like. For example, the porous material can comprise stainless steel, nickel, a nickel alloy (e.g., Hastelloy), titanium, a titanium alloy, chromium, a chromium alloy, aluminum, an aluminum alloy, aluminum oxide, aluminum nitride, boron nitride, zirconia, silicon nitride, tricalcium phosphate, hydroxyl apatite, hydroxy apatite, zirconium-toughened alumina, alumina-toughened zirconia, and/or the like. In various examples, the lift pin material configured to abut the susceptor material when disposed in a susceptor pin hole (e.g., the porous material and/or solid material of the outer pin surface) can comprise a different material than the material of the susceptor. In various examples, a porous material can comprise a sintered material.

To form a lift pin (or a portion thereof) comprising a sintered material, a powder and/or fiber material (e.g., comprising any of the materials discussed herein, such as metal, metal alloy, metal oxide, ceramic, etc.), can be pressed together to form an object (e.g., a sheet or block of sintered material). The powder and/or fiber material can be pressed under any suitable conditions, including any suitable temperature or pressure, and for any suitable duration to achieve the object comprising sintered material. The object comprising a sintered material can be formed into any desired shape to form the lift pin (or portion thereof). For example, the object comprising a sintered material can be cut (e.g., via machining, laser cutting, and/or the like) to form a desired shape. In various examples, the lift pin comprising a porous material can be formed via additive manufacturing (e.g., 3D printing, binder jetting, and/or the like).

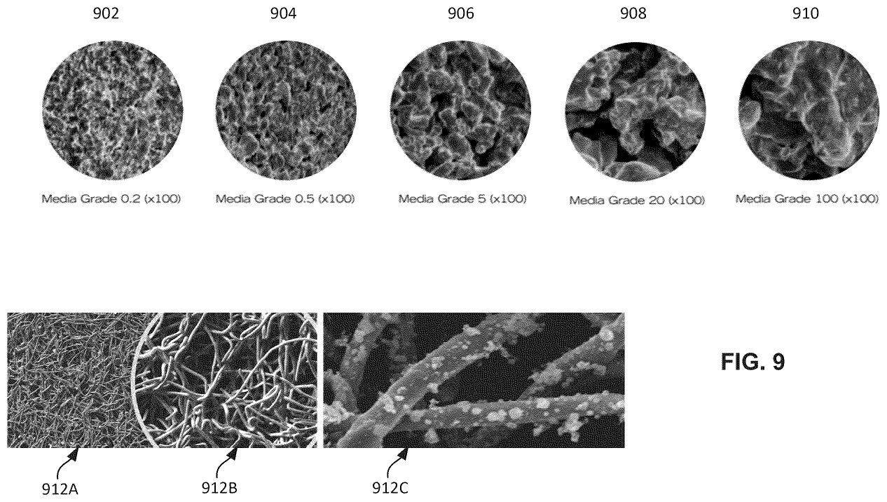

In various examples, the powder and/or fiber used to form a porous lift pin can comprise any suitable size. For example, the porous material can be formed from particles ranging in size from 0.2 media grade to 100 grade media (“media grade,” or other similar term, being the particle size in micrometers), 0.2 to 5 media grade, 0.5 to 5 media grade, 5 to 100 media grade, 5 to 20 media grade, or 20 to 100 media grade. With reference to FIG. 9, for a more tightly or densely packed porous material, a relatively smaller powder material can be used, such as porous material 902 comprising grade 0.2 media. For relatively less tightly or densely packed porous material, a relatively larger powder material may be used, such as porous material 910 comprising grade 100 media. Porous materials 904, 906, and 908 depict other powder sizes of 0.5, 5, and 20 media grade, respectively, to create porous material. Fibrous material 912B (a magnified view of fibrous material 912A) can also be used to form the porous material, as discussed herein. In various examples, pore size within the porous material can be any suitable size, such as 0.2 micrometer to 100 micrometers. The porosity of a porous material comprised in a lift pin can be 10-96%, 30-90%, 40-70%, or 50-60%.

As shown in FIG. 9, the spaces between the porous material (i.e., the pores within the porous material) can provide significant space for fluid to travel therein through the lift pin in the susceptor (and thus, between the upper and lower chambers of the reactor). Additionally, the relatively massive amount of surface area of the porous material provides huge numbers of sites upon which contaminants may deposit and be trapped. Thus, fluid can pass through the porous material of a lift pin, and the porous material can capture contaminants (e.g., as shown by fibrous material 912C and the contaminants captured thereon).

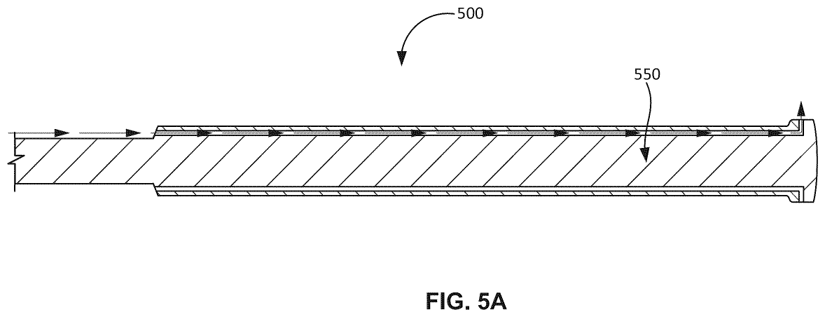

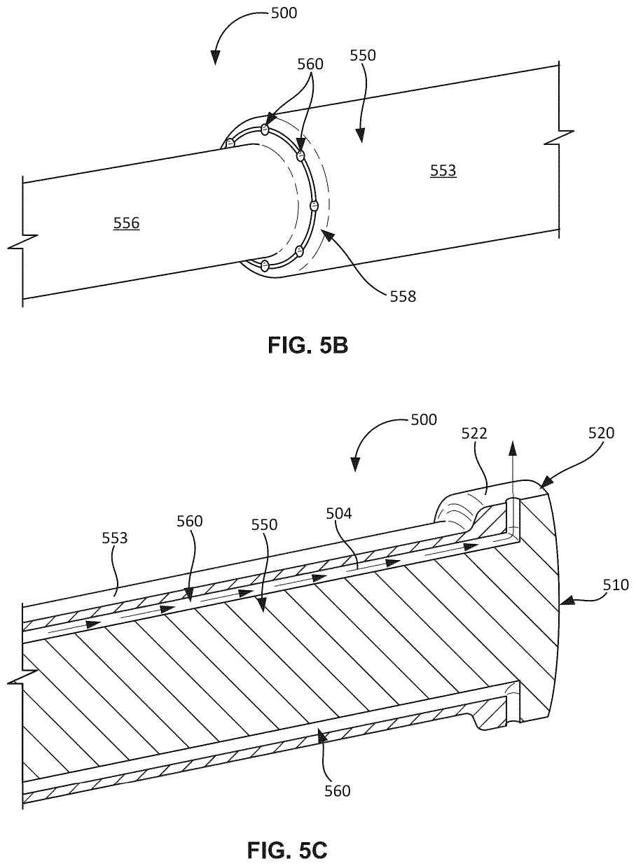

In various examples, the fluid path within a lift pin can comprise a pin channel configured to allow fluid to pass through the lift pin between upper and lower chambers of a reactor. With reference to FIGS. 5A-5C, a lift pin 500 can comprise a pin body 550. Pin body can comprise a portion having a shape and size complementary to a respective pin hole in a susceptor in which lift pin 500 will be disposed. For example, pin body 550 can comprise upper body portion 553 having a shape complementary to a pin hole in a susceptor, and a lower body portion 556 having a cross-sectional area smaller than upper body portion 553. Transition portion 558 can span between upper body portion 553 and lower body portion 556, bridging the size difference between the two.

Lift pin 500 can comprise pin channels 560. Pin channels 560 can span in any suitable direction to facilitate fluid 504 flowing through lift pin 500, and thus between the respective upper and lower chambers in a reactor. For example, pin channels 560 can span linearly and parallel to an axis on which the pin body spans. In various examples, the pin channel can span between the pin top end and the pin bottom end in any suitable configuration (e.g., in a path that is non-linear, non-parallel to the spanning of the pin body, in a serpentine, helical, or any other desired configuration). In various examples, the pin channel can span far enough from the pin top end toward the pin bottom end such that when the lift pin is disposed in its respective pin hole in the susceptor, and a substrate is disposed on and in contact with the susceptor, the upper chamber and the lower chamber are in fluid communication via the pin channel. In various examples, the pin channel can span from the pin top end (e.g., pin top end 410 of lift pin 400) to the pin bottom end (e.g., pin bottom end 490). In various examples, pin channels 560 can span from the pin top end 510 to transition portion 558 of pin body 550 (in channels 560 can be open at transition portion 558 of pin body 550). Pin channels 560 can be open to pin top end 510 (i.e., spanning all the way through pin head 520), and/or as shown in FIG. 5C, pin channels 560 can change direction in pin head 520 to open to pin head outer surface 522.

A pin channel can comprise any suitable configuration. For example, pin channels 560 can be fulling enclosed within the lift pin (within a lift pin cross-section), or pin channels may not be fully enclosed within the pin body of the lift pin (e.g., a pin channel can be open and recessed into the pin outer surface).

In various examples, with reference to FIG. 3, upper chamber 312 and lower chamber 314 can be substantially fluidly separate except for through the fluid path in the lift pin(s) (e.g., through porous material and/or a pin channel in the lift pin). (As used herein, “substantially fluidly separate,” “sealed,” “substantially sealed,” and/or other like terms or phrases can mean completely fluidly separate and/or sealed except for unintentional leakage.). The amount of fluid flow and/or flow rate through the fluid path comprised in the lift pin (e.g., from the porous material and/or pin channel(s)), can be tuned via the porosity (e.g., choosing less or more densely packed material for sintering or the like) and/or the pin channel size, shape, and/or pathway/route.

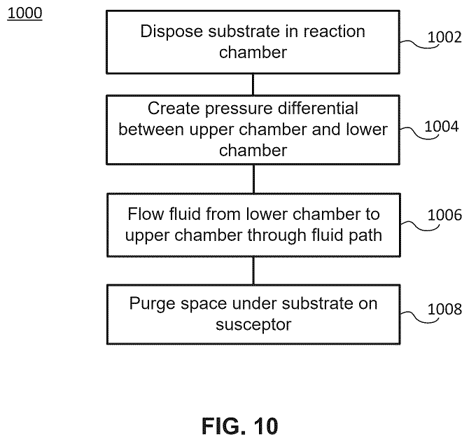

With additional reference to FIG. 10, a method 1000 for processing a substrate in a reaction chamber is illustrated, in accordance with various embodiments. It should also be appreciated that the examples of the disclosure can be utilized in a reaction chamber configured for a multitude of deposition processes, including but not limited to, ALD, CVD, metalorganic chemical vapor deposition (MOCVD), molecular beam epitaxy (MBE), and physical vapor deposition (PVD). The examples of the disclosure can also be utilized in reaction chambers configured for processing a substrate with a reactive precursor, which can also include etch processes, such as, for example, reactive ion etching (RIE), inductively coupled plasma etching (ICP), and electron cyclotron resonance etching (ECR).

In various examples, with reference to FIGS. 2A, 2B, and 10, substrate 150 can be disposed in reaction chamber 110 (step 1002). In various examples, substrate 150 can be disposed directly on substrate support surface 135 of susceptor 130. In various examples, substrate 150 can be disposed on lift pins 200 protruding from substrate support surface 135 of susceptor 130. In such examples, lift pins 200 and/or susceptor 130 can be moved relative to the other such that pin top end is flush with substrate support surface 135 of susceptor 130 or lower than substrate support surface 135 (i.e., pin top end 410 being disposed at least partially within susceptor 130) such that substrate 150 is disposed directly on, and in contact with, substrate support surface 135. In various examples, lift pins 200 can receive substrate 150, susceptor 130 can be moved upward while lift pins 200 remain stationary, such that lift pins 200 recess into susceptor 130 and pin holes 137, and susceptor 130 receives substrate 150 onto substrate support surface 135 and disposes susceptor 130 in processing position 106 in upper chamber 112.

In various examples, a pressure differential can be created between upper chamber 112 and lower chamber 114 (step 1004). A vacuum source 92 can be used to evacuate reaction chamber 110 and/or lower chamber 114. A flow controller 94 can be fluidly coupled to lower chamber 114 via a lower chamber inlet to provide fluid flow into lower chamber 114, increasing the pressure therein. The pressure in upper chamber 112 can remain the same, or increase at less of a rate than the pressure in lower chamber 114 (e.g., while flow controller 94 is causing fluid flow into lower chamber 114). As shown in FIG. 3, flow controller 394 can provide the fluid flow into lower chamber 314, increasing the pressure therein relative to the upper chamber 312. Vacuum source 392 can be used to evacuate upper chamber 312 and/or lower chamber 314. With reference again to FIGS. 2A and 2B, upper chamber 112 can comprise an upper chamber pressure, and lower chamber 114 can comprise a lower chamber pressure. Flow controller 94 (or any other suitable device) can cause the lower chamber pressure to be greater than the upper chamber pressure.

Susceptor 130 can comprise at least one pin hole 137 traversing susceptor 130 from substrate support surface 135 to susceptor bottom surface 136 (or at least a portion therebetween), each having a lift pin 200 disposed therein. One or more of the lift pins can comprise a fluid path therethrough. As discussed herein, the fluid path can be comprised in a porous material of the lift pin and/or in one or more pin channels disposed through the lift pin. As discussed herein, the fluid path in the lift pin can span any suitable length of the pin body such that, when lift pin 200 is disposed in pin hole 137 of susceptor 130, and the pin top end is flush with or below substrate support surface 135, upper chamber 112 and lower chamber 114 can be in fluid communication through the fluid path through lift pin 200.

In response to creating the pressure differential between upper chamber 112 and lower chamber 114 (i.e., upper chamber 112 having a lower pressure than lower chamber 114), fluid can flow from lower chamber 114 to upper chamber 112 through the fluid path in lift pins 200 (step 1006), for example, through the lift pin comprising a porous material and/or through a pin channel in the lift pin. The amount and/or rate of fluid flow through the lift pins can be any suitable and/or desired level, which can be tuned based on the porous material used, the porosity of the porous material, and/or the size/configuration of a pin channel through the lift pin. For example, the flow rate through the lift pin can be 1-20 standard cubic centimeters per minute (sccm), 2-10 sccm, or about 5 sccm (wherein “about” means plus or minus 2 sccm). The fluid flowing through lift pins 200 can pass under substrate 150, thus purging the space under substrate 150 (e.g., between susceptor 130 and substrate 150) (step 1008) and/or the space around the edges of substrate 150. In various examples, with momentary reference to FIG. 3, pin hole 337 and/or the fluid path through lift pin 299 can be in fluid communication with susceptor channel 334. Accordingly, fluid can flow from lower chamber 314, through lift pin 299, and through and along susceptor channel 334, beneath substrate 350 disposed on susceptor 330, purging the underside and/or edges of substrate 150. Thus, contamination and/or deposition on the underside and/or edges of substrate 150 can be decreased or prevented. Additionally, the pressure differential with lower chamber 114 having a higher pressure than upper chamber 112 can cause any fluid leakage between lower chamber 114 and upper chamber 112 to be flowing from lower chamber 114 to upper chamber 112. Thus, precursor gas and/or other materials from upper chamber 112 can be at least partially inhibited or prevented from flowing to lower chamber 114, as fluid from lower chamber 114 flows to upper chamber 112.

In various examples, the steps of method 1000 for purging the underside (i.e., backside) and/or edge of substrate 150 on substrate support surface 135 (e.g., steps 1004-1008) can be applied throughout substrate processing, and/or at any suitable time and in any suitable manner. For example, the steps of method 1000 can be performed continuously before, during, and/or between deposition cycles. As another example, the steps of method 1000 can be performed before and/or during each deposition cycle (i.e., before, and/or throughout, each application of material by showerhead 180, with breaks between deposition cycles during drying/baking to form the resulting layer on substrate 150).

In various examples, deposition cycles can be performed on the substrate 150 until a desired chemical system of layers of desired thickness is disposed on substrate 150. In response, substrate 150 can be removed from reaction chamber 110. To do so, susceptor 130 and/or lift pins 200 can move relative to one another. For example, susceptor 130 can move downward in reaction chamber 110 relative to lift pins 200, and/or lift pins 200 can move upward relative to susceptor 130 in reaction chamber 110. Thus, substrate 150 can be elevated by lift pins 200 away from substrate support surface 135 of susceptor 130, which can facilitate substrate 150 removal from reaction chamber 110.

Although exemplary embodiments of the present disclosure are set forth herein, it should be appreciated that the disclosure is not so limited. For example, although reactor systems are described in connection with various specific configurations, the disclosure is not necessarily limited to these examples. Various modifications, variations, and enhancements of the system and method set forth herein can be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

What is claimed is:

1. A reactor system, comprising:
a reaction chamber;
a susceptor disposed in the reaction chamber, wherein the susceptor is disposed between an upper chamber and a lower chamber comprised in the reaction chamber,
wherein the susceptor comprises a pin hole disposed through the susceptor such that the pin hole is in fluid communication with the upper chamber and the lower chamber, and such that the upper chamber is in fluid communication with the lower chamber; and
a lift pin disposed in the pin hole, wherein the lift pin comprises a pin body, wherein the pin body comprises a porous material configured to allow a fluid to flow through the lift pin between the upper chamber and the lower chamber.

2. The reactor system of claim 1, wherein the upper chamber is substantially fluidly sealed from the lower chamber except through the pin hole with the lift pin disposed therein.

3. The reactor system of claim 1, wherein the lower chamber comprises a lower chamber inlet through which fluid flows into the lower chamber.

4. The reactor system of claim 3, wherein the lower chamber comprises a lower chamber pressure and the upper chamber comprises an upper chamber pressure, wherein the lower chamber pressure is greater than the upper chamber pressure, such that fluid flows from the lower chamber through the porous material in the lift pin into the upper chamber.

5. The reactor system of claim 4, wherein the susceptor comprises a support surface configured to support a substrate, wherein the support surface comprises a susceptor channel recessed into the susceptor that is open to the support surface and in fluid communication with the pin hole.

6. The reactor system of claim 5, wherein the susceptor channel in the susceptor is configured to allow fluid to flow from the pin hole and through the susceptor channel when the substrate is disposed on the support surface, such that the fluid flows under the substrate and is configured to purge contaminants from under the substrate.

7. The reactor system of claim 1, wherein the porous material comprises a sintered material.

8. The reactor system of claim 1, wherein the pin body further comprises a solid portion surrounding the porous material.

9. The reactor system of claim 8, wherein the solid portion of the pin body is a solid sleeve, and wherein the porous material is disposed in the solid sleeve.

10. The reactor system of claim 1, wherein the lift pin comprises a pin head at a top end of the pin body, wherein the pin head comprises the porous material, wherein the pin head is disposed at least partially in the pin hole of the susceptor.

11. A lift pin configured to be disposed in a susceptor comprised in a reactor system, comprising:
a pin body comprising a porous material, wherein the porous material is configured to allow a fluid to flow through at least a portion of the pin length.

12. The lift pin of claim 11, wherein the porous material comprises a sintered material.

13. The lift pin of claim 11, wherein the pin body further comprises a solid portion surrounding the porous material.

14. The lift pin of claim 11, wherein the solid portion of the pin body is a solid sleeve, and wherein the porous material is disposed in the solid sleeve.

15. A reactor system, comprising:
a reaction chamber; and
a susceptor disposed in the reaction chamber, wherein the susceptor is disposed between an upper chamber and a lower chamber comprised in the reaction chamber, the susceptor comprising:
a support surface configured to support a substrate; and
a fluid path disposed through the susceptor and the support surface, wherein the fluid path fluidly connects the upper chamber and the lower chamber,
wherein the lower chamber comprises a lower chamber pressure, and the upper chamber comprises an upper chamber pressure, wherein the lower chamber pressure is greater than the upper chamber pressure, such that fluid flows from the lower chamber through the fluid path into the upper chamber.

16. The reactor system of claim 15, wherein the susceptor further comprises a susceptor channel recessed into the susceptor through the support surface that is open to the support surface and fluidly connected to the fluid path.

17. The reactor system of claim 15, wherein the susceptor further comprises a pin hole disposed through the susceptor, and wherein the reactor system further comprises a lift pin disposed in the pin hole, wherein the lift pin comprises the fluid path such that the fluid flows through the lift pin.

18. The reactor system of claim 17, wherein the lift pin comprises a porous material, wherein the porous material comprises the fluid path.

19. The reactor system of claim 18, wherein the porous material comprises a sintered material.

20. The reactor system of claim 18, wherein the pin body further comprises a solid portion surrounding the porous material.
